(19) United States
(12) Patent Application Publication
(10) Pub. No.: US 2008/0185038 A1
(43) Pub. Date: Aug. 7, 2008

(54) Inverted metamorphic solar cell with via for backside contacts

(75) Inventor: Paul R. Sharps, Albuquerque, NM (US)

Correspondence Address: Casey Toohey;Emcore Corporation, 1600 Eubank Blvd. SE, Albuquerque, NM, 87123, US

(73) Assignee: Emcore Corporation

(21) Appl. No.: 11/701,741

(22) Filed: Feb. 2, 2007

(51) Int. Cl. H01L 31/00

(52) U.S. Cl. 136/255; 438/94; 257/E31.001

(57) ABSTRACT

A method of forming a multijunction solar cell comprising an upper subcell, a middle subcell, and a lower subcell by providing a first substrate for the epitaxial growth of semiconductor material; forming a first solar subcell on said substrate having a first band gap; forming a second solar subcell over said first subcell having a second band gap smaller than said first band gap; forming a grading interlayer over said second subcell having a third band gap larger than said second band gap; forming a third solar subcell having a fourth band gap smaller than said second band gap such that said third subcell is lattice mismatched with respect to said second subcell; and etching a via from the top of the third subcell to the substrate to enable both anode and cathode contacts to be placed on the backside of the solar cell.

### REFERENCE TO RELATED APPLICATIONS

This application is also related to co-pending U.S. patent application Ser. No. 11/109,016 filed Apr. 19, 2005.

This application is also related to co-pending U.S. patent application Ser. No. 11/445,793 filed Jun. 2, 2006.

This application is also related to co-pending U.S. patent application Ser. No. 11/500,053 filed Aug. 7, 2006.

### BACKGROUND OF THE INVENTION

1. Field of the Invention

The present invention relates to the field of solar cell semiconductor devices, and particularly to integrated semiconductor structures including a multijunction solar cell and a conducting via that allows both anode and cathode terminals to be placed on the back side of the cell.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, the design efficiency of solar cells, which act as the power conversion devices for the on-board power systems, become increasingly more important.

Solar cells are often fabricated in vertical, multijunction structures, and disposed in horizontal arrays, with the individual solar cell connected together in a series. The shape and structure of an array, as well as the number of cells it contains, are determined in part by the desired output voltage and current.

Inverted metamorphic solar cell structures such as described in U.S. Pat. No. 6,951,819, the paper of M. W. Wanless et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), and co-pending U.S. patent application Ser. No. 11/445,793 filed Jun. 2, 2006, of the present assignee, present an important development in future commercial solar cell products.

Since a solar cell is fabricated as a vertical, multijunction structure, one electrical contact is usually placed on the top surface of the cell, and the other contact on the bottom of the cell, to avoid internal interconnections which may affect reliability and cost. A variety of designs are also known in which both contacts are placed on one side of the cell, including as represented in U.S. patent application Ser. No. 11/109,016 of the instant assignee.

Prior to the present invention, there has not been a inverted metamorphic solar cell with both anode and cathode contacts on the same side of the cell.

### SUMMARY OF THE INVENTION

### 1. Objects of the Invention

It is an object of the present invention to provide an improved multijunction solar cell with both anode and cathode contacts on the backside of the cell.

It is an object of the invention to provide an improved inverted metamorphic solar cell.

It is another object of the invention to provide an electrical interconnection via in a multi-solar cell structure that is fabricated on a substrate which is removed during processing.

It is still another object of the invention to provide a method of manufacturing an inverted metamorphic solar cell as a thin, flexible film with contacts on one side of the cell.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### 2. Features of the Invention

Briefly, and in general terms, the present invention provides a method of manufacturing a solar cell by providing a first substrate; depositing on the substrate a sequence of layers of semiconductor material that forms at least one cell of a multifunction solar cell; etching a via from the top surface of the sequence of layers to the first substrate; providing a second substrate over the sequence of layers, and removing the first substrate.

In another aspect, the present invention provides a method of manufacturing a solar cell having a front side and back side by providing a first substrate; depositing on the substrate a sequence of layers of semiconductor material that forms at least one cell of a multijunction solar cell; providing a second substrate over the sequence of layers; and removing the first substrate. A first electrode is then formed on the back side of the solar cell, and an electrical connection is formed between the top cell of the multijunction solar cell and a second electrode on the back side of the solar cell.

In another aspect, the present invention provides a solar cell including a semiconductor body having a sequence of layers forming a multijunction solar cell including; a first solar subcell having a first band gap; a second solar subcell disposed over the first subcell and having a second band gap smaller than the first band gap; a grading interlayer disposed over the second subcell having a third band gap larger than the second band gap, and a third subcell disposed over the interlayer such that the third solar subcell is lattice mismatched with respect to the second subcell and has a fourth band gap smaller than the third band gap, with anode and cathode contacts on the backside of the solar cell.

In another aspect of the present invention provides a multijunction solar cell having a front side surface and a back side surface including a first solar subcell adjacent the front side surface having a first band gap; a second solar subcell disposed over the first subcell and having a second band gap smaller than said first band gap; a grading interlayer disposed over the second subcell and having a third band gap greater than the second band gap; and a third solar subcell adjacent the back side surface and disposed over the interlayer, the third subcell being lattice mismatched with respect to said second subcell and having a fourth band gap smaller than the third band gap. A via is formed in the first, second, and third solar cells with an electrical conductor extending through the via. An insulated contact pad is provided on the back side surface and electrically connected to the conductor to form a first terminal of the solar cell on the back side surface. A second terminal is formed on the back side surface by a metal layer making contact with a contact layer on the back side.

### BRIEF DESCRIPTION OF THE DRAWINGS

These and other features and advantages of this invention will be better and more fully appreciated by reference to the following detailed description when considered in conjunction with the accompanying drawings, wherein:

FIG. 1 is an enlarged cross-sectional view of the solar cell structure according to the present invention at the end of the process steps of forming a multijunction solar cell on a first substrate;

FIG. 2 is a cross-sectional view of the structure of FIG. 1 with a via etched to the first substrate;

FIG. 3 is a cross-sectional view of the solar cell structure of FIG. 2 after the next process step according to the present invention including depositing a dielectric layer and a conductive layer in the via;

FIG. 4 is a cross-sectional view of the solar cell of FIG. 3 after the next process step according to the present invention in which a wafer carrier or surrogate second substrate is adhered to the “top” side of the solar cell structure;

FIG. 5 is a cross-sectional view of the solar cell of FIG. 4 after the next process step according to the present invention in which the first substrate is removed;

FIG. 6 is a cross-sectional view of the solar cell of FIG. 5 after the next process step according to the present invention in which a cap layer and metal contact layer is deposited on the structure;

FIG. 7 is a cross-sectional view of the solar cell of FIG. 6 after the next process step according to the present invention in which a cover glass is adhered to the solar cell structure on one side, and the surrogate second substrate removed on the other side; and

FIGS. 8A and 8B are top and bottom plan views, respectively, of a wafer including the solar cell of the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

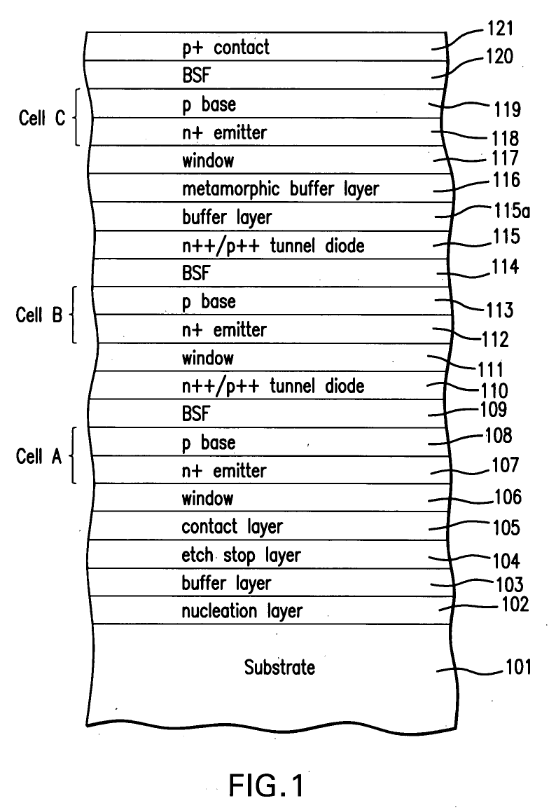

FIG. 1 depicts the multijunction solar cell according to the present invention after formation of the three subcells A, B and C on a substrate. More particularly, there is shown a first substrate 101, which may be either gallium arsenide (GaAs), germanium (Ge), or other suitable material. In the case of a Ge substrate, a nucleation layer 102 such as InGaP₂, is deposited on the substrate. On the substrate, or over the nucleation layer 102 in the case of a Ge substrate, a buffer layer 103 of InGaAs, and an etch stop layer 104 of InAlP₂ are further deposited. A contact layer 105 of InGaAs is then deposited on layer 104, and a window layer 106 of InAlP₂ is deposited on the contact layer. The subcell A, consisting of an n+ emitter layer 107 of InGaP₂ and a p-type base layer 108 of InGaP₂, is then deposited on the window layer 106.

Although the preferred embodiment utilizes the III-V semiconductor materials described above, the embodiment is only illustrative, and it should be noted that the multijunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

In the preferred embodiment, the substrate 101 is gallium arsenide, the emitter layer 107 is composed of InGa(Al)P₂, and the base layer is composed of InGa(Al)P₂. The use of parenthesis in the formula is standard nomenclature to indicate that the amount of aluminum may vary from 0 to 30%.

On top of the base layer 108 is deposited a p+ type back surface field (“BSF”) layer 109 of InGaAlP which is used to reduce recombination loss.

The BSF layer 109 drives minority carriers from the region near the base/BSF interface surface to minimize the effect of recombination loss. In other words, a BSF layer 109 reduces recombination loss at the backside of the solar subcell A and thereby reduces the recombination in the base.

On top of the BSF layer 109 is deposited a sequence of heavily doped p-type (such as AlGaAs) and n-type layers 110 (such as InGaP₂) which forms a tunnel diode which is a circuit element to connect cell A to cell B.

On top of the tunnel diode layers 110 a window layer 111 of n++ InAlP₂ is deposited. The window layer 111 used in the subcell B also operates to reduce the recombination loss. The window layer 111 also improves the passivation of the cell surface of the underlying junctions. It should be apparent to one skilled in the art that additional layer(s) may be added or deleted in the cell structure without departing from the scope of the present invention.

On top of the window layer 111 the layers of cell B are deposited: the emitter layer 112, and the p-type base layer 113. These layers are preferably composed of InGaP₂ for the emitter and either GaAs or In_{0.015}GaAs for the base, respectively, although any other suitable materials consistent with lattice constant and band gap requirements may be used as well.

On top of the cell B is deposited a BSF layer 114 of p+ type AlGaAs which performs the same function as the BSF layer 109. A p++/n++ tunnel diode 115 is deposited over the BSF layer 114 similar to the layers 110, again forming a circuit element to connect cell B to cell C. A buffer layer 115a, preferably InGaAs, is deposited over the tunnel diode 115, with a thickness of about 1.0 micron. A metamorphic buffer layer 116 is then deposited over the buffer layer 115a. The layer 116 is preferably a compositionally step-graded composition of InGaAlAs deposited as a series of layers with monotonically changing lattice constant that provides a transition in lattice constant from cell B to subcell C. The bandgap of layer 116 is 1.5 ev constant with a value slightly greater than the bandgap of the middle cell B.

In one embodiment, as suggested in the Wanless et al. paper, the step grade contains nine compositionally graded steps with each step layer having a thickness of 0.25 micron. In the preferred embodiment, the interlayer is composed of InGaAlAs, with monotonically changing lattice constant.

On top of the metamorphic buffer layer 116 another n+ window layer 117 is deposited. The window layer 117 improves the passivation of the cell surface of the underlying junctions. Additional layers may be provided without departing from the scope of the present invention.

On top of the window layer 117 the layers of subcell C are deposited; the n-type emitter layer 118 and the p type base layer 119. In the preferred embodiment, the emitter layer is composed of GaInAs and the base layer is composed of GaInAs with about a 1.0 ev bandgap, although any other semiconductor materials with suitable lattice constant and band gap requirements may be used as well.

On top of the base layer 119 of subcell C a back surface field (BSF) layer 120, preferably composed of GaInAsP, is deposited.

Over or on top of the BSF layer 120 is deposited a p+ contact layer 121, preferably of p+ type InGaAs.

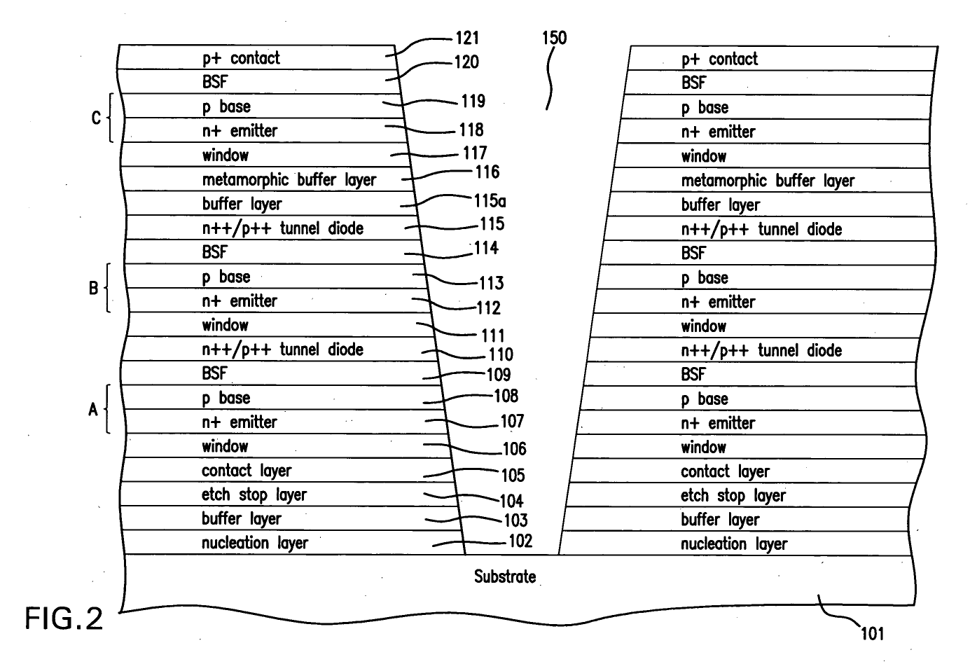

FIG. 2 is a cross-sectional view of the structure of FIG. 1 after the process step of a via 150 being etched from the top surface of the deposited layers 102 through 121 by dry or wet chemical processes to the substrate 101.

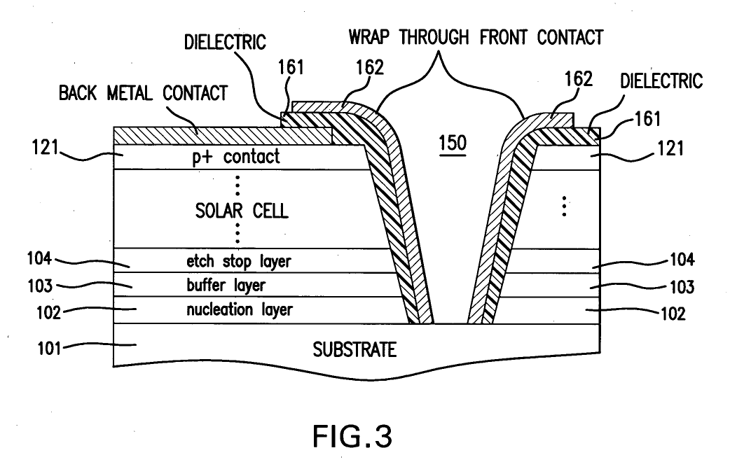

FIG. 3 is a cross-sectional view of the solar cell structure of FIG. 2 after the next sequence of process step according to the present invention including depositing a back metal layer over the p+ contact layer 121, and depositing a dielectric layer 161 in the interior of the via 150 and over a portion of the back metal contact layer. A conductive layer 162 is then deposited in the via 150 and over the dielectric layer 161. The layer 162 serves as a wrap through front contact for the solar cell.

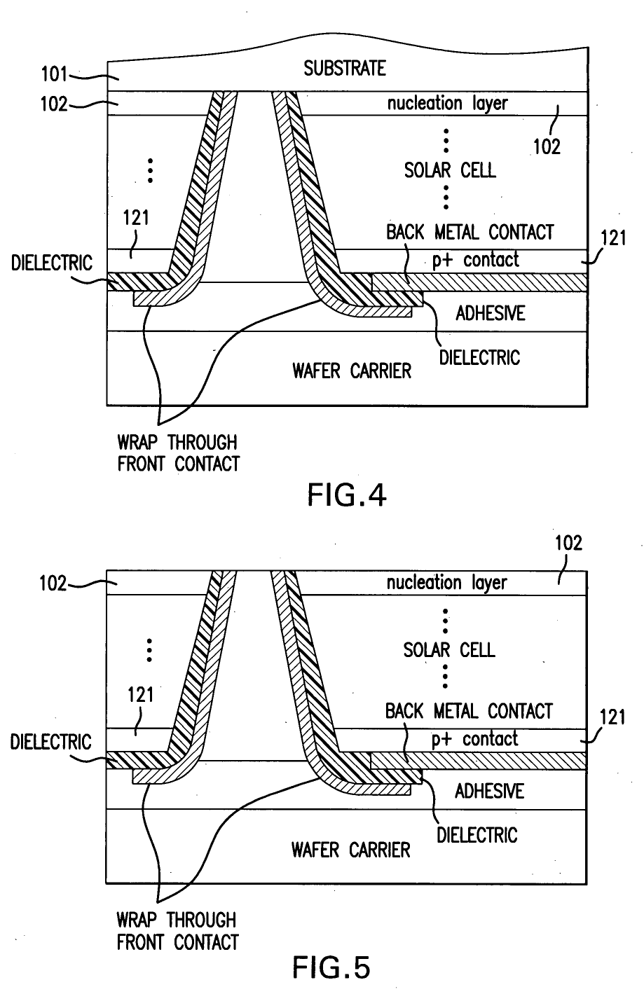

FIG. 4 is a cross-sectional view of the solar cell of FIG. 3 (how oriented with the substrate 101 at the top of the Figure) after the next process step according to the present invention. A wafer carrier or surrogate second substrate is adhered to the “top” side of the solar cell structure, which is now at the bottom of the Figure. In the preferred embodiment, the surrogate substrate is sapphire about 1000 microns in thickness, and is perforated with holes about 1 mm in diameter, spaced 4 mm apart, to aid in subsequent removal of the substrate.

FIG. 5 is a cross-sectional view of the solar cell of FIG. 4 after the next process step according to the present invention in which the first substrate 101 is removed by a lapping or grinding process.

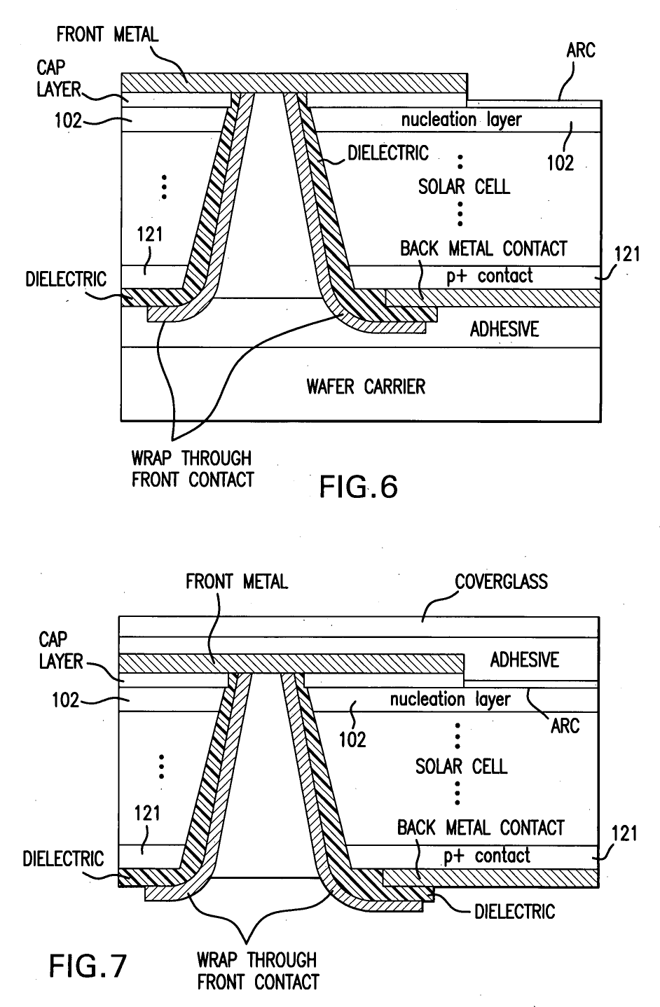

FIG. 6 is a cross-sectional view of the solar cell of FIG. 5 after the next process step according to the present invention in which a cap layer is deposited over a portion of the nucleation layer in the region of the via 150 and metal contact layer is deposited over the cap layer, making electrical contact with the metal layer 161 inside the via 150. An antireflective coating (ARC) layer is then applied over the surface of the nucleation layer.

FIG. 7 is a cross-sectional view of the solar cell of FIG. 6 after the next process step according to the present invention in which an adhesive is applied over the front metal layer and the ARC layer, and a cover glass is adhered to the solar cell structure. On the other side, the surrogate second substrate is then removed by dissolving the adhesive attaching it, or any other suitable technique.

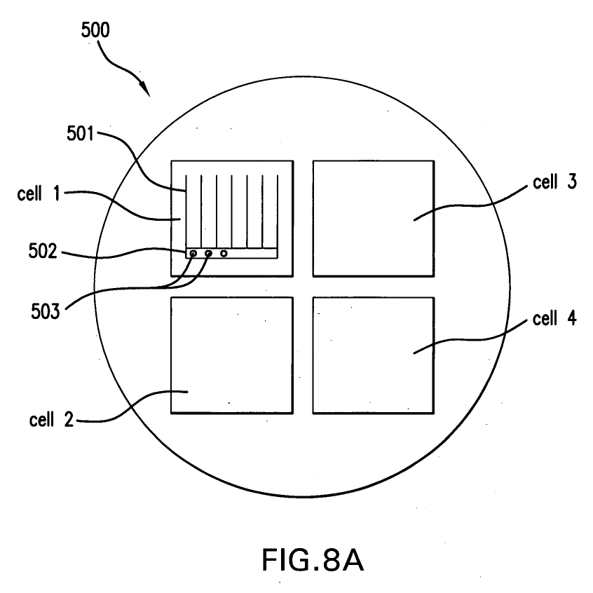

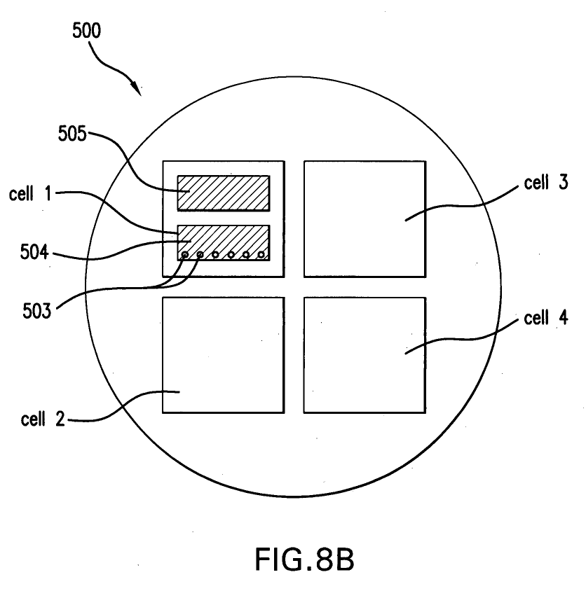

FIGS. 8A and 8B are top and bottom plan views, respectively of a wafer including the solar cell of the present invention. In FIG. 8A, Cell 1 of each wafer is illustrated in greater detail with grid lines 501, a bus 502, and circular regions 503 in which a via 150 extends through the wafer such as shown in previous cross-sectional views.

FIG. 8B depicts the back side contact region 505 and a wrap through front contact region 504 with vias 503 corresponding to those shown in FIG. 8A.

It will be understood that each of the elements described above, or two or more together, also may find a useful application in other types of constructions differing from the types of constructions differing from the types described above.

While the invention has been illustrated and described as embodied in a multijunction inverted metamorphic solar cell, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a solar cell comprising:
providing a first substrate;
depositing on said substrate a sequence of layers of semiconductor material that forms at least one cell of a multijunction solar cell;
etching a via from the top surface of said sequence of layers to said first substrate;
providing a second substrate over said second region; and
removing said first substrate.

2. A method as defined in claim 1, further comprising depositing a layer of dielectric material circumferentially around the inside surface of the via.

3. A method as defined in claim 2, further comprising depositing a conductive layer over said layer of dielectric material extending throughout the via.

4. A method as defined in claim 3, further comprising depositing a front metal grid on the front surface of the solar cell electrically connected to said conductive layer.

5. A method as defined in claim 4, further comprising depositing first and second electrode contact pads on the back surface of said solar cell, said first electrode contact pad being electrically connected to said conductive layer.

6. A method as defined in claim 1, wherein said step of depositing a sequence of layers of semiconductor material comprises forming a first solar subcell on said substrate having a first band gap; forming a second solar subcell over said first subcell having a second band gap smaller than said first band gap; forming a grading interlayer over said second subcell having a third band gap larger than said second band gap; forming a third solar subcell having a fourth band gap smaller than said second band gap such that said third subcell is lattice mismatched with respect to said second subcell.

7. A method of manufacturing a solar cell as defined in claim 1, wherein said first substrate is composed of GaAs.

8. A method of manufacturing a solar cell as defined in claim 6, wherein said first solar subcell is composed of an InGa(Al)P emitter region and an InGa(Al)P base region.

9. A method of manufacturing a solar cell as defined in claim 6, wherein said second solar subcell is composed of an InGaP₂ emitter region and an In_{0.015}GaAs base region.

10. A method of manufacturing a solar cell as defined in claim 6, wherein said grading interlayer is composed of InGaAlAs.

11. A method of manufacturing a solar cell as defined in claim 6, wherein the grading interlayer is composed of a plurality of layers with monotonically increasing lattice constant.

12. A method of manufacturing a solar cell having a front side and back side comprising:
providing a first substrate;
depositing on said substrate a sequence of layers of semiconductor material that forms at least one cell of a multifunction solar cell;
providing a second substrate over said second region;
removing said first substrate;
forming a first electrode on the back side of the solar cell; and
forming an electrical connection between the top cell of the multijunction solar cell and a second electrode on the back side of the solar cell.

13. A method as defined in claim 12, further comprising forming a via through said sequence of layers and depositing a layer of dielectric material circumferentially around the inside surface of the via.

14. A method as defined in claim 13, further comprising depositing a conductive layer over said layer of dielectric material extending throughout the via to form said electrical connection.

15. A method as defined in claim 14, further comprising depositing a front metal grid on the front surface of the solar cell electrically connected to said conductive layer.

16. A method as defined in claim 12, wherein said step of depositing a sequence of layers of semiconductor material comprises forming a first solar subcell on said substrate having a first band gap; forming a second solar subcell over said first subcell having a second band gap smaller than said first band gap; forming a grading interlayer over said second subcell having a third band gap larger than said second band gap; forming a third solar subcell having a fourth band gap smaller than said third band gap such that said third subcell is lattice mismatched with respect to said second subcell.

17. A multijunction solar cell comprising:
a first solar subcell having a first band gap;
a second solar subcell disposed over said first subcell and having a second band gap small than said first band gap;
a grading interlayer disposed over said second subcell and having a third band gap greater than said second band gap;
a third solar subcell disposed over said interlayer that is lattice mismatched with respect to said second subcell and having a fourth band gap smaller than said third band gap; and
anode and cathode contacts to said solar cell disposed on the surface of said solar cell adjacent said third solar subcell.

18. A multifunction solar cell as defined in claim 17 and having a front side surface and a back side surface, wherein the first solar subcell is disposed adjacent said front side surface, and said third solar subcell is disposed adjacent said back side surface, and further comprising:
a via formed in said first, second, and third solar subcells;
an electrical conductor extending through said via; and
an insulated contact pad on said back side surface and electrically connected to said conductor to form said cathode contact of said solar cell on said back side surface.
